(19) United States
(12) Patent Application Publication
(10) Pub. No.: US 2023/0317594 A1
(43) Pub. Date: Oct. 5, 2023

(54) DEVICE PERFORMANCE TUNING BY DEEP TRENCH VIA (DVB) PROXIMITY EFFECT IN ARCHITECTURE OF BACKSIDE POWER DELIVERY

(71) Applicants: Tao CHU, Portland, OR (US); Minwoo JANG, Portland, OR (US); Aurelia WANG, Hillsboro, OR (US); Conor P. PULS, Portland, OR (US); Lin HU, Portland, OR (US); Jaladhi MEHTA, Beaverton, OR (US); Brian GREENE, Portland, OR (US); Chung-Hsun LIN, Portland, OR (US); Walid M. HAFEZ, Portland, OR (US); Paul PACKAN, Hillsboro, OR (US)

(72) Inventors: Tao CHU, Portland, OR (US); Minwoo JANG, Portland, OR (US); Aurelia WANG, Hillsboro, OR (US); Conor P. PULS, Portland, OR (US); Lin HU, Portland, OR (US); Jaladhi MEHTA, Beaverton, OR (US); Brian GREENE, Portland, OR (US); Chung-Hsun LIN, Portland, OR (US); Walid M. HAFEZ, Portland, OR (US); Paul PACKAN, Hillsboro, OR (US)

(21) Appl. No.: 17/710,802

(22) Filed: Mar. 31, 2022

(51) Int. Cl. H01L 23/522; H01L 27/088; H01L 29/417; H01L 29/423; H01L 23/528

(52) U.S. Cl. CPC H01L 23/5226; H01L 27/088; H01L 27/0886; H01L 29/41775; H01L 29/41791; H01L 29/42392; H01L 23/5283; H01L 23/5286; H01L 29/0673

(57) ABSTRACT

Embodiments disclosed herein include a semiconductor device. In an embodiment, the semiconductor device comprises a substrate and a transistor over the substrate. In an embodiment, the transistor comprises a source, a gate, and a drain. In an embodiment, the semiconductor device further comprises a first metal layer above the transistor, where the first metal layer comprises, a source metal coupled to the source, a drain metal coupled to the drain, and a gate metal coupled to the gate. In an embodiment, the source metal, the drain metal, and the gate metal are parallel conductive lines. In an embodiment, a backside via passes through the substrate, and a contact metal in the first metal layer is coupled to the backside via. In an embodiment, the contact metal is oriented orthogonal to the source metal.

### TECHNICAL FIELD

Embodiments of the disclosure are in the field of semiconductor structures and processing and, in particular, to device tuning using deep trench vias for backside power delivery.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1A is a plan view illustration of a semiconductor device with a backside via adjacent to a drain of a transistor device, in accordance with an embodiment.

FIG. 1B is a plan view illustration of a semiconductor device with a backside via three units away from the drain of a transistor device, in accordance with an embodiment.

FIG. 1C is a plan view illustration of a semiconductor device with a backside via five units away from the drain of a transistor device, in accordance with an embodiment.

FIG. 1D is a plan view illustration of a semiconductor device with a backside via eight units away from the drain of a transistor device, in accordance with an embodiment.

FIG. 2 is a plan view illustration of a plurality of transistors with backside vias positioned adjacent to the plurality of transistors in order to provide different switching speeds to the plurality of transistors, in accordance with an embodiment.

FIG. 3A is a cross-sectional illustration of a tri-gate transistor device with a backside via, in accordance with an embodiment.

FIG. 3B is a cross-sectional illustration of a gate-all-around (GAA) transistor with a backside via, in accordance with an embodiment.

FIG. 4 illustrates a computing device in accordance with one implementation of an embodiment of the disclosure.

FIG. 5 is an interposer implementing one or more embodiments of the disclosure.

### DESCRIPTION OF THE EMBODIMENTS

Embodiments described herein comprise device tuning using deep trench vias for backside power delivery. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

To provide context, existing semiconductor devices utilize a library of available transistor architectures in order to provide circuitry with a desired performance. Each of the transistor architectures in the library include different knobs that can be adjusted in order to modulate the performance of the transistor. For example, fin number or ribbon size may be used as one knob, Vt type can be used as another knob, and super-nesting strain effect can be used as yet another knob. However, such knobs are typically limited in that they provide digital changes to the performance of the transistor architecture. For example, fin number or ribbon size can be used to define a low power or a high power performance. That is, there is currently, no available knob that allows for continuous parameter tuning.

Accordingly, embodiments disclosed herein include a transistor architecture that allows for continuous parameter tuning. Particularly, it has been shown that deep trench vias to provide power from the backside of the wafer can be used to modulate device characteristics. By increasing or decreasing the distance of the backside via from the transistor, device performance/leakage can be tuned to be up to 10% faster or 30%-40% lower leakage. Without being tied to a particular mechanism, it is believed that the strain effect from the backside via or fixed charge during the process results in the change in the device performance.

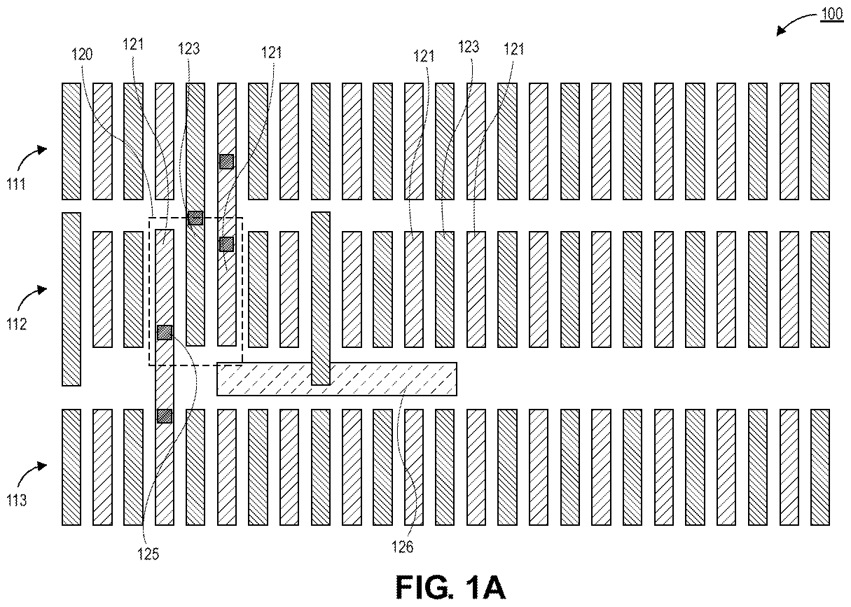

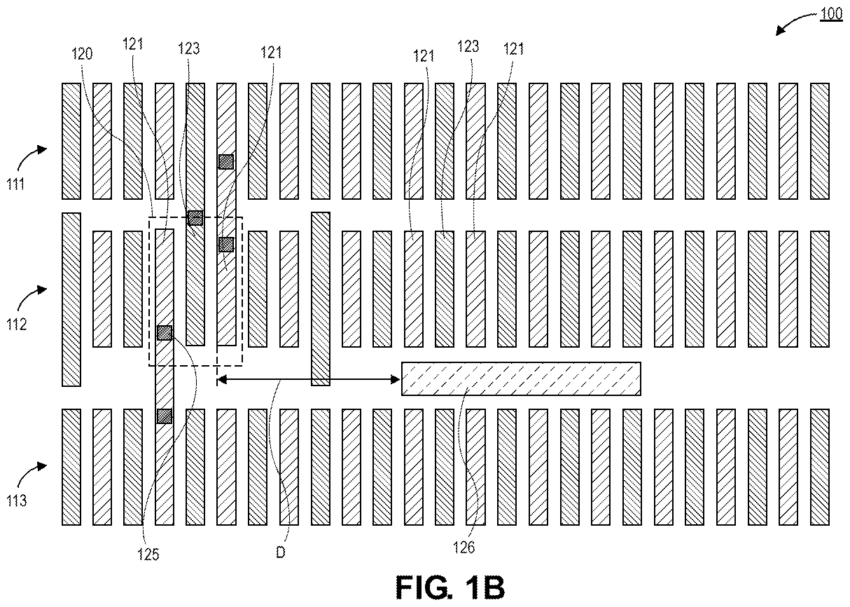

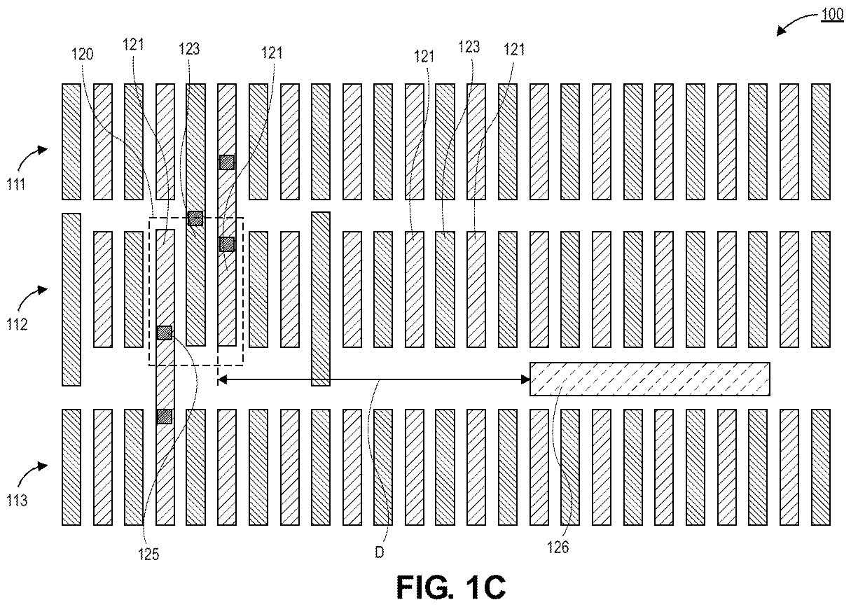

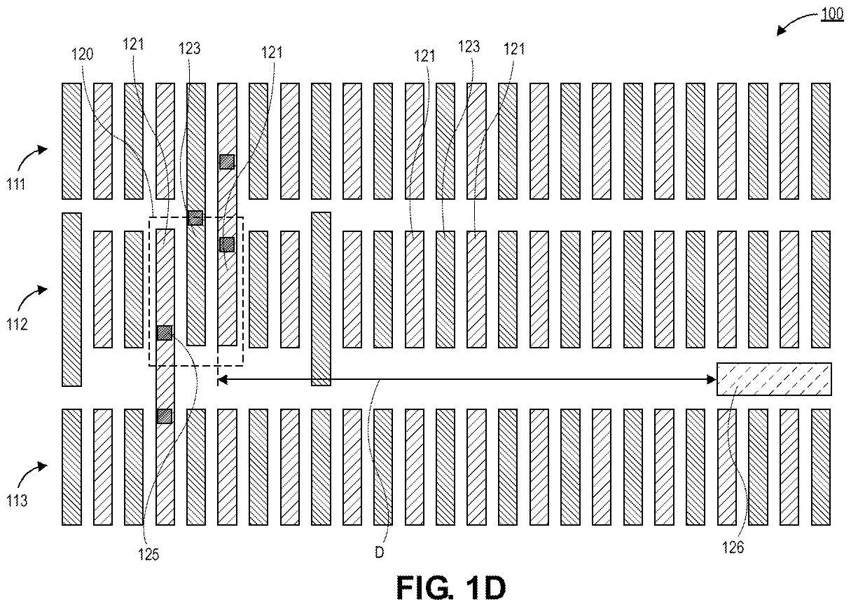

Referring now to FIG. 1A, a plan view illustration of a semiconductor device 100 is shown, in accordance with an embodiment. Particularly, the first metal layer over the transistor devices (not shown) is shown in FIG. 1A. The first metal layer may include a plurality of rows 111, 112, and 113 of devices. While three rows are shown, it is to be appreciated that any number of rows may be included. In an embodiment, the rows 111, 112, and 113 may comprise a plurality of parallel metal traces. For ease of illustration, source/drain metal traces 121 are shown with a first shading and gate metal traces 123 are shown with a second shading. However, it is to be appreciated that the materials for the source/drain metal traces 121 and the gate metal traces 123 may be substantially similar.

In FIG. 1A, a dashed box 120 is provided around a pair of source/drain metal traces 121 and a gate metal trace 123 in the second row 112 to indicate the presence of a single transistor device. As show, the source/drain metal traces 121 and the gate metal trace 123 may extend outside the dashed box 120 to indicate that the transistor device may be coupled to other transistor devices in the adjacent rows 111 and 113. In an embodiment, vias 125 may be provided below the source/drain metal traces 121 and the gate metal trace 123 in order to indicate the connection to the underlying structures of the transistor (e.g., the source/drain regions, the gate stack, or the like).

In an embodiment, the transistor device within the dashed box 120 may be any type of transistor device. In a particular embodiment, the transistor device is a non-planar transistor device. For example, the transistor device may be a tri-gate transistor device, a gate-all-around (GAA) transistor device, or the like. While a single dashed box 120 highlights one of the transistor devices in the semiconductor device 100, it is to be appreciated that other transistor devices may be provided in the first row 111, the second row 112, and the third row 113.

In an embodiment, a backside via trace 126 is provided between the second row 112 and the third row 113. The backside via trace 126 may be coupled to a backside via that extends through the backside of the semiconductor device in order to provide power delivery to transistor devices. For example, the backside via may pass through a semiconductor substrate, such as a silicon substrate. In an embodiment, the backside via trace 126 may be oriented substantially orthogonal to the source/drain metal traces 121 and the gate metal traces 123. In the illustrated embodiment, a backside via trace 126 is shown between the second row 112 and the third row 113, but additional backside via traces 126 may be provided between the first row 111 and the second row 112. Additionally, while a single backside via trace 126 is shown in FIG. 1A, it is to be appreciated that multiple backside via traces 126 may be provided between the rows 111, 112, and 113. Particularly, segmenting a backside via trace 126 into a plurality of backside via traces 126 allows for individually tuning the various transistor devices, as will be described in greater detail below.

In an embodiment, the backside via trace 126 is provided at least partially adjacent to the transistor device in the dashed box 120. For example, the backside via trace 126 is immediately adjacent to the right source/drain metal trace 121. As used herein, immediately adjacent may refer to the orientation of two structures where an orthogonal line out from the surface of one structure intersects a portion of the other structure. For example, in FIG. 1A, a bottom surface of the right source/drain metal trace 121 in the dashed box 120 is immediately adjacent to a top surface of the backside via trace 126. Placing the backside via trace 126 immediately adjacent to the source/drain metal trace 121 induces a strain in the transistor device and modulates the performance of the transistor device (e.g., a switching speed and/or a leakage current).

Referring now to FIG. 1B, a plan view illustration of a semiconductor device 100 is shown, in accordance with an additional embodiment. In an embodiment, the semiconductor device 100 in FIG. 1B may be substantially similar to the semiconductor device 100 in FIG. 1A, with the exception of the placement of the backside via trace 126. For example, the semiconductor device 100 may include a plurality of rows 111, 112, and 113 that include source/drain metal traces 121 and gate metal traces 123. A dashed box 120 highlights the location of a single transistor device in the semiconductor device 100.

In the embodiment shown in FIG. 1B, the position of the backside via trace 126 is shifted compared to the positon of the backside via trace in FIG. 1A. Instead of being immediately adjacent to the source/drain metal trace 121, the backside via trace 126 is shifted to the right a distance D. In an embodiment, the distance D may be any distance in order to modulate the effect of strain on the transistor device within the dashed box 120. For example, the greater the distance D, the less strain is induced in the transistor device. In a particular embodiment, the distance D is approximately equal to six times the pitch between source/drain metal traces 121 and the gate metal traces 123. A distance of six times the pitch results in the backside via trace 126 being shifted over a total of three source/drain metal traces 121.

Referring now to FIG. 1C, a plan view illustration of a semiconductor device 100 is shown, in accordance with an additional embodiment. In an embodiment, the semiconductor device 100 in FIG. 1C may be substantially similar to the semiconductor device 100 in FIG. 1A, with the exception of the placement of the backside via trace 126. For example, the semiconductor device 100 may include a plurality of rows 111, 112, and 113 that include source/drain metal traces 121 and gate metal traces 123. A dashed box 120 highlights the location of a single transistor device in the semiconductor device 100.

In the embodiment shown in FIG. 1C, the position of the backside via trace 126 is shifted compared to the positon of the backside via trace in FIG. 1A. Instead of being immediately adjacent to the source/drain metal trace 121, the backside via trace 126 is shifted to the right a distance D. In an embodiment, the distance D may be any distance in order to modulate the effect of strain on the transistor device within the dashed box 120. For example, the greater the distance D, the less strain is induced in the transistor device. In a particular embodiment, the distance D is approximately equal to ten times the pitch between source/drain metal traces 121 and the gate metal traces 123. A distance of ten times the pitch results in the backside via trace 126 being shifted over a total of five source/drain metal traces 121.

Referring now to FIG. 1D, a plan view illustration of a semiconductor device 100 is shown, in accordance with an additional embodiment. In an embodiment, the semiconductor device 100 in FIG. 1D may be substantially similar to the semiconductor device 100 in FIG. 1A, with the exception of the placement of the backside via trace 126. For example, the semiconductor device 100 may include a plurality of rows 111, 112, and 113 that include source/drain metal traces 121 and gate metal traces 123. A dashed box 120 highlights the location of a single transistor device in the semiconductor device 100.

In the embodiment shown in FIG. 1D, the position of the backside via trace 126 is shifted compared to the positon of the backside via trace in FIG. 1A. Instead of being immediately adjacent to the source/drain metal trace 121, the backside via trace 126 is shifted to the right a distance D. In an embodiment, the distance D may be any distance in order to modulate the effect of strain on the transistor device within the dashed box 120. For example, the greater the distance D, the less strain is induced in the transistor device. In a particular embodiment, the distance D is approximately equal to sixteen times the pitch between source/drain metal traces 121 and the gate metal traces 123. A distance of sixteen times the pitch results in the backside via trace 126 being shifted over a total of eight source/drain metal traces 121.

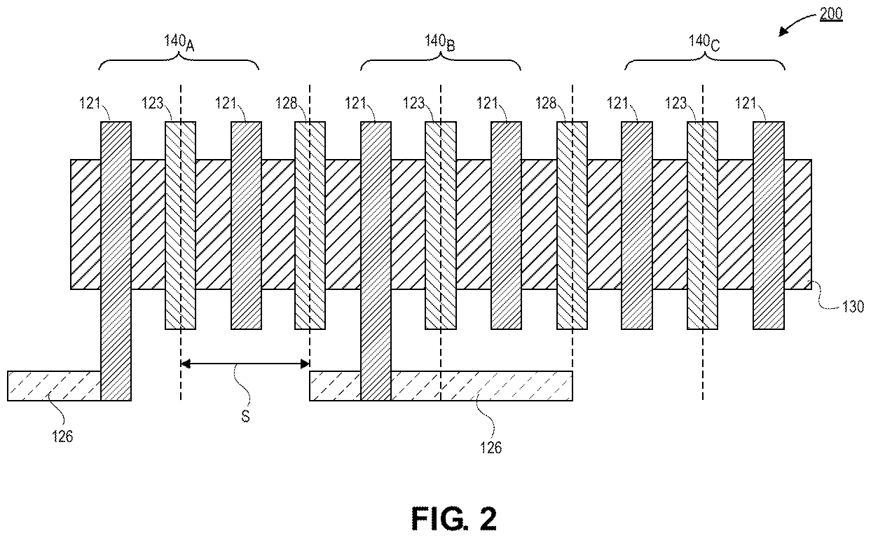

Referring now to FIG. 2, a plan view illustration of a semiconductor device 200 is shown, in accordance with an embodiment. In an embodiment, the semiconductor device 200 may comprise a plurality of transistor devices 140A, 140B, and 140c that adjacent to each other in a row. In an embodiment, each transistor device 140 may comprise a pair of source/drain metal traces 121 and a gate metal trace 123. The neighboring transistor devices 140 may be separated from each other by dummy gate metal traces 128. In an embodiment, the source/drain metal traces 121 and the gate metal traces 123 may be substantially parallel to each other. The source/drain metal trace 121 and the gate metal traces 123 may cross over a channel structure 130. For example, the channel structure 130 may be a fin, a stack of nanowires, or a stack of nanoribbons. Source/drain regions (not shown) may also be provided along the channel structure 130 below the source/drain metal traces 121.

In an embodiment one or more backside via traces 126 may be provided below the plurality of transistor devices 140. The backside via trace 126 may be substantially orthogonal to the source/drain metal traces 121 and the gate metal traces 123. In an embodiment, placement of the backside via trace 126 allows for tuning of the performance of the transistor devices 140. For example, since the backside via trace 126 is below the second transistor device 140B, the second transistor device 140E may have a slower switching speed than the transistor devices 140A and 140c. Additionally, by controlling how far the transistor device 140 is from the backside via trace 126, continuous control of device parameters may be provided.

In a particular embodiment, the distance between the source/drain metal trace 121 and the backside via trace 126 may be variable between the transistor devices. For example, the first transistor device 140A may have a backside via trace 126 a first distance from a source/drain metal trace 121, and a second transistor device 140E may have a backside via trace 126 that is a second (different) distance from the source/drain metal trace 121. As such, the performance of the first transistor device 140A may be different than the performance of the second transistor device 140B.

Additionally, it is to be appreciated that the variable distances between the source/drain metal trace 121 and the backside via trace 126 can be modulated between many different positions in order to provide a library of device performances that can be chosen in order to provide desired circuit performance for the semiconductor device. For example, as shown in FIGS. 1A-1D, various architectures may be included in the library, and a particular one of the architectures may be chosen for a given application.

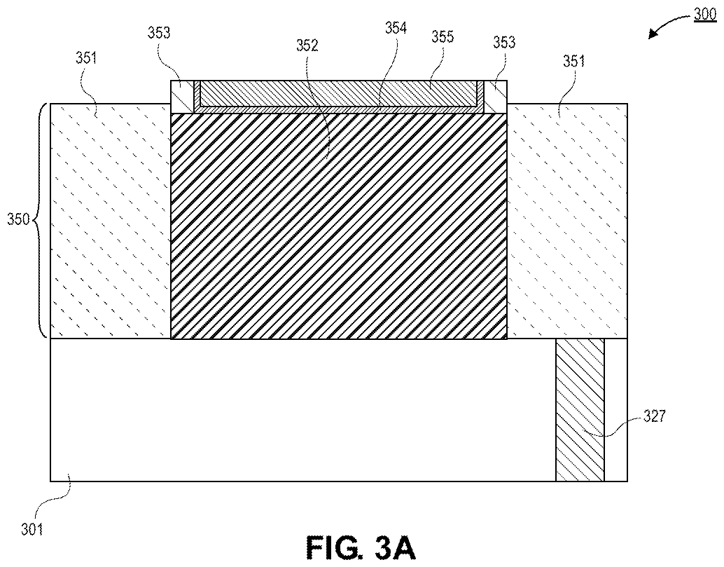

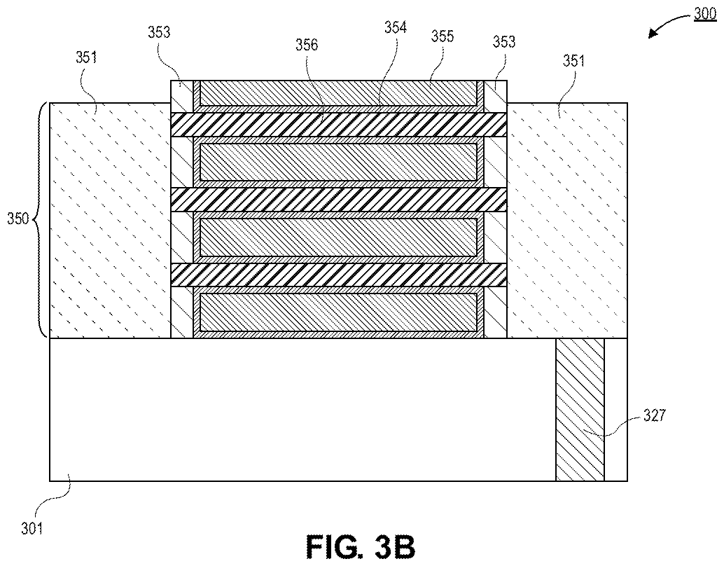

Referring now to FIGS. 3A and 3B, cross-sectional illustrations of non-planar transistor devices that include backside vias are shown, in accordance with various embodiments. FIG. 3A illustrates a tri-gate transistor structure, and FIG. 3B illustrates a GAA transistor structure.

Referring now to FIG. 3A, a cross-sectional illustration of a semiconductor device 300 is shown, in accordance with an embodiment. In an embodiment, the semiconductor device 300 comprises a transistor 350 over a substrate 301. The substrate 301 may be a semiconductor substrate. The semiconductor substrate 301 often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as substrates including germanium, carbon, or Group III-V materials.

In an embodiment, a semiconductor fin 352 extends between source/drain regions 351. A gate stack may be provided within spacers 353. The gate stack may include a gate dielectric 354 and a gate electrode 355. While shown over the top surface of the fin 352 in FIG. 3A, it is to be appreciated that the gate stack wraps around sidewalls of the fin 352 into and out of the plane of FIG. 3A to provide tri-gate control of the fin 352.

The gate dielectric 354 may be, for example, any suitable oxide such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric 454 to improve its quality when a high-k material is used.

In an embodiment, the gate metal 355 may include a workfunction metal and a fill metal. In an embodiment, when the workfunction metal will serve as an N-type workfunction metal, the workfunction metal preferably has a workfunction that is between about 3.9 eV and about 4.2 eV. N-type materials that may be used to form the workfunction metal include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the workfunction metal will serve as a P-type workfunction metal, the workfunction metal preferably has a workfunction that is between about 4.9 eV and about 5.2 eV. P-type materials that may be used to form the workfunction metal include, but are not limited to, ruthenium, palladium, platinum, cobalt, nickel, and conductive metal oxides, e.g., ruthenium oxide.

As shown, a backside via 327 is provided through the substrate 301 to contact a source/drain region 351. In an embodiment, the backside via 327 may be directly coupled to the source/drain region 351. In other embodiments, the backside via 327 may be electrically coupled to a backside via trace, such as those described in greater detail above. In an embodiment, the backside via trace may run substantially parallel to the fin 352. The positioning of the backside via trace relative to the source/drain regions 351 may be used to induce strain in the transistor 350 in order to provide a mechanism to continuously modulate performance of the transistor 350 (e.g., switching speed, leakage, etc.).

Referring now to FIG. 3B a cross-sectional illustration of a semiconductor device 300 is shown, in accordance with an additional embodiment. In an embodiment, the semiconductor device 300 comprises a transistor 350 over a substrate 301, such as a silicon substrate or the like. In an embodiment, a plurality of semiconductor nanowires 356 or nanoribbons, extend between source/drain regions 351. A gate stack may be provided around the nanowires 356 between spacers 353. In an embodiment, the gate stack may include a gate dielectric 354 and a gate electrode 355. The gate dielectric 354 and the gate electrode 355 may include materials similar to those described above with respect to FIG. 3A. In an embodiment, the gate stack wraps completely around a perimeter of the nanowires 356 (into and out of the plane of FIG. 3B) to provide GAA control of the nanowires 356.

As shown, a backside via 327 is provided through the substrate 301 to contact a source/drain region 351. In an embodiment, the backside via 327 may be directly coupled to the source/drain region 351. In other embodiments, the backside via 327 may be electrically coupled to a backside via trace, such as those described in greater detail above. In an embodiment, the backside via trace may run substantially parallel to the fin 352. The positioning of the backside via trace relative to the source/drain regions 351 may be used to induce strain in the transistor 350 in order to provide a mechanism to continuously modulate performance of the transistor 350 (e.g., switching speed, leakage, etc.).

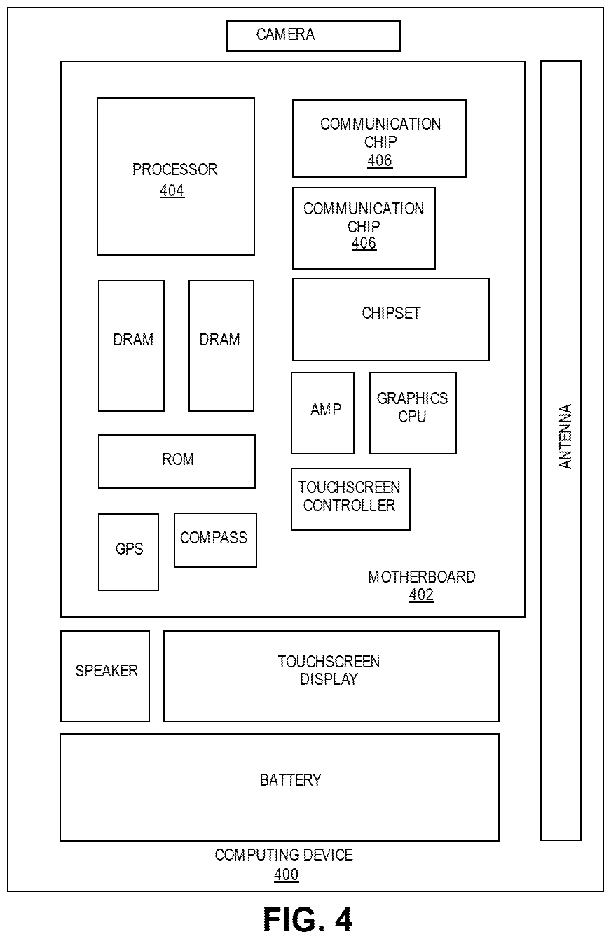

FIG. 4 illustrates a computing device 400 in accordance with one implementation of an embodiment of the disclosure. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In an embodiment, the integrated circuit die of the processor may comprise a transistor device with a backside via trace that is spaced a distance D from the source/drain metal trace of the transistor device in order to control transistor performance, as described herein. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In an embodiment, the integrated circuit die of the communication chip may comprise a transistor device with a backside via trace that is spaced a distance D from the source/drain metal trace of the transistor device in order to control transistor performance, as described herein.

In further implementations, another component housed within the computing device 400 may comprise a transistor device with a backside via trace that is spaced a distance D from the source/drain metal trace of the transistor device in order to control transistor performance, as described herein.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

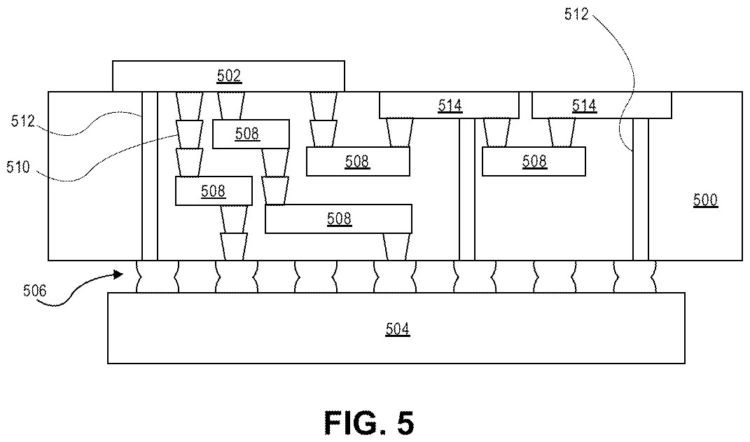

FIG. 5 illustrates an interposer 500 that includes one or more embodiments of the disclosure. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. In an embodiment, one of both of the first substrate 502 and the second substrate 504 may comprise a transistor device with a backside via trace that is spaced a distance D from the source/drain metal trace of the transistor device in order to control transistor performance, in accordance with embodiments described herein. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer 500 may be formed of alternate rigid or flexible materials that may include the same materials described above for use in a semiconductor substrate, such as silicon, germanium, and other group III-V and group IV materials.

The interposer 500 may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the disclosure, apparatuses or processes disclosed herein may be used in the fabrication of interposer 500.

Thus, embodiments of the present disclosure may comprise a transistor device with a backside via trace that is spaced a distance D from the source/drain metal trace of the transistor device in order to control transistor performance.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a semiconductor device, comprising: a substrate; a transistor above the substrate, wherein the transistor comprises a source, a gate, and a drain; a first metal layer above the transistor, wherein the first metal layer comprises: a source metal coupled to the source; a drain metal coupled to the drain; and a gate metal coupled to the gate, wherein the source metal, the drain metal, and the gate metal are parallel conductive lines; a backside via passing through the substrate; and a contact metal in the first metal layer that is coupled to the backside via, wherein the contact metal is oriented orthogonal to the source metal.

Example 2: the semiconductor device of Example 1, wherein the contact metal is adjacent to an end of the drain metal.

Example 3: the semiconductor device of Example 1 or Example 2, wherein the source metal, the drain metal, and the gate metal have a pitch.

Example 4: the semiconductor device of Example 3, wherein the contact metal is spaced away from an edge of the drain metal by three times the pitch.

Example 5: the semiconductor device of Example 3, wherein the contact metal is spaced away from an edge of the drain metal by five times the pitch.

Example 6: the semiconductor device of Example 3, wherein the contact metal is spaced away from an edge of the drain metal by eight times the pitch.

Example 7: the semiconductor device of Examples 1-6, wherein the transistor is a non-planar transistor.

Example 8: the semiconductor device of Example 7, wherein the transistor is a tri-gate transistor.

Example 9: the semiconductor device of Example 7, wherein the transistor is a gate-all-around (GAA) transistor.

Example 10: a semiconductor device, comprising: a first transistor, wherein the first transistor is coupled to a first source metal, a first drain metal, and a first gate metal, wherein the first source metal, the first drain metal, and the first gate metal are parallel traces in a first metal layer above the first transistor; a second transistor adjacent to the first transistor, wherein the second transistor is coupled to a second source metal, a second drain metal, and a second gate metal, wherein the second source metal, the second drain metal, and the second gate metal are parallel to the first source metal; a first backside via adjacent to an edge of the first gate metal; and a second backside via in line with the first backside via and spaced away from an edge of the second gate metal.

Example 11: the semiconductor device of Example 10, wherein the first source metal, the first drain metal, and the first gate metal have a pitch.

Example 12: the semiconductor device of Example 11, wherein the second backside via is spaced away from the edge of the second gate metal by at least one pitch.

Example 13: the semiconductor device of Example 11, wherein the second backside via is spaced away from the edge of the second gate metal by at least three pitches.

Example 14: the semiconductor device of Example 11, wherein the second backside via is spaced away from the edge of the second gate metal by at least five pitches.

Example 15: the semiconductor device of Example 11, wherein the second backside via is spaced away from the edge of second gate metal by at least eight pitches.

Example 16: the semiconductor device of Examples 10-15, wherein the first transistor has a first switching speed, and wherein the second transistor has a second switching speed that is greater than the first switching speed.

Example 17: the semiconductor device of Examples 10-16, further comprising: a dummy gate metal between the first transistor and the second transistor.

Example 18: the semiconductor device of Examples 10-17, wherein a length of the first backside via is different than a length of the second backside via.

Example 19: the semiconductor device of Examples 10-18, wherein the first backside via and the second backside via are orthogonal to the first source metal.

Example 20: the semiconductor device of Examples 10-19, wherein the first transistor and the second transistor are tri-gate transistors or gate-all-around (GAA) transistors.

Example 21: a semiconductor device, comprising: a first transistor with a first drain metal that is spaced away from a first backside via by a first distance; and a second transistor with second drain metal that is spaced away from a second backside via by a second distance that is different than the first distance.

Example 22: the semiconductor device of Example 21, wherein the first distance is greater than the second distance, and wherein the first transistor has a first switching speed that is greater than a second switching speed of the second transistor.

Example 23: the semiconductor device of Example 21 or Example 22, wherein the first transistor is adjacent to the second transistor, wherein a dummy gate metal separates the first transistor from the second transistor.

Example 24: an electronic system, comprising: a board; a package substrate coupled to the board; and a die coupled to the package substrate, wherein the die comprises: a first transistor with a first drain metal that is spaced away from a first backside via by a first distance; and a second transistor with second drain metal that is spaced away from a second backside via by a second distance that is different than the first distance.

Example 25: the electronic system of Example 24, wherein the first distance is greater than the second distance, and wherein the first transistor has a first switching speed that is greater than a second switching speed of the second transistor.

What is claimed is:

1. A semiconductor device, comprising:
a substrate;
a transistor above the substrate, wherein the transistor comprises a source, a gate, and a drain;
a first metal layer above the transistor, wherein the first metal layer comprises:
a source metal coupled to the source;
a drain metal coupled to the drain; and
a gate metal coupled to the gate, wherein the source metal, the drain metal, and the gate metal are parallel conductive lines;
a backside via passing through the substrate; and
a contact metal in the first metal layer that is coupled to the backside via, wherein the contact metal is oriented orthogonal to the source metal.

2. The semiconductor device of claim 1, wherein the contact metal is adjacent to an end of the drain metal.

3. The semiconductor device of claim 1, wherein the source metal, the drain metal, and the gate metal have a pitch.

4. The semiconductor device of claim 3, wherein the contact metal is spaced away from an edge of the drain metal by three times the pitch.

5. The semiconductor device of claim 3, wherein the contact metal is spaced away from an edge of the drain metal by five times the pitch.

6. The semiconductor device of claim 3, wherein the contact metal is spaced away from an edge of the drain metal by eight times the pitch.

7. The semiconductor device of claim 1, wherein the transistor is a non-planar transistor.

8. The semiconductor device of claim 7, wherein the transistor is a tri-gate transistor.

9. The semiconductor device of claim 7, wherein the transistor is a gate-all-around (GAA) transistor.

10. A semiconductor device, comprising:
a first transistor, wherein the first transistor is coupled to a first source metal, a first drain metal, and a first gate metal, wherein the first source metal, the first drain metal, and the first gate metal are parallel traces in a first metal layer above the first transistor;
a second transistor adjacent to the first transistor, wherein the second transistor is coupled to a second source metal, a second drain metal, and a second gate metal, wherein the second source metal, the second drain metal, and the second gate metal are parallel to the first source metal;
a first backside via adjacent to an edge of the first gate metal; and
a second backside via in line with the first backside via and spaced away from an edge of the second gate metal.

11. The semiconductor device of claim 10, wherein the first source metal, the first drain metal, and the first gate metal have a pitch.

12. The semiconductor device of claim 11, wherein the second backside via is spaced away from the edge of the second gate metal by at least one pitch.

13. The semiconductor device of claim 11, wherein the second backside via is spaced away from the edge of the second gate metal by at least three pitches.

14. The semiconductor device of claim 11, wherein the second backside via is spaced away from the edge of the second gate metal by at least five pitches.

15. The semiconductor device of claim 11, wherein the second backside via is spaced away from the edge of second gate metal by at least eight pitches.

16. The semiconductor device of claim 10, wherein the first transistor has a first switching speed, and wherein the second transistor has a second switching speed that is greater than the first switching speed.

17. The semiconductor device of claim 10, further comprising:
a dummy gate metal between the first transistor and the second transistor.

18. The semiconductor device of claim 10, wherein a length of the first backside via is different than a length of the second backside via.

19. The semiconductor device of claim 10, wherein the first backside via and the second backside via are orthogonal to the first source metal.

20. The semiconductor device of claim 10, wherein the first transistor and the second transistor are tri-gate transistors or gate-all-around (GAA) transistors.

21. A semiconductor device, comprising:
a first transistor with a first drain metal that is spaced away from a first backside via by a first distance; and
a second transistor with second drain metal that is spaced away from a second backside via by a second distance that is different than the first distance.

22. The semiconductor device of claim 21, wherein the first distance is greater than the second distance, and wherein the first transistor has a first switching speed that is greater than a second switching speed of the second transistor.

23. The semiconductor device of claim 21, wherein the first transistor is adjacent to the second transistor, wherein a dummy gate metal separates the first transistor from the second transistor.

24. An electronic system, comprising:
a board;
a package substrate coupled to the board; and
a die coupled to the package substrate, wherein the die comprises:
a first transistor with a first drain metal that is spaced away from a first backside via by a first distance; and
a second transistor with second drain metal that is spaced away from a second backside via by a second distance that is different than the first distance.

25. The electronic system of claim 24, wherein the first distance is greater than the second distance, and wherein the first transistor has a first switching speed that is greater than a second switching speed of the second transistor.
